(19) United States
(12) Patent Application Publication
(10) Pub. No.: US 2012/0115316 A1
(43) Pub. Date: May 10, 2012

(54) Crystallization apparatus, crystallization method, and method of manufacturing organic light-emitting display device, which use sequential lateral solidification

(76) Inventor: Cheol-Ho Park, Yongin-City (KR)

(21) Appl. No.: 13/317,693

(22) Filed: Oct. 26, 2011

(30) Foreign Application Priority Data
Nov. 5, 2010 (KR) 10-2010-0109777

(51) Int. Cl. H01L 21/20; B05C 9/12; H01L 21/268

(52) U.S. Cl. 438/487; 438/795; 118/620; 257/E21.134; 257/E21.347

(57) ABSTRACT

A crystallization apparatus, which uses sequential lateral solidification (SLS) and crystallizes an amorphous silicon layer formed on a substrate, includes a laser generating device, a first optical system, a second optical system, and a path switching member. The laser generating device is configured to emit a laser beam. The first optical system is configured to process the laser beam emitted from the laser generating device and to irradiate the processed laser beam onto the substrate. The second optical system is parallel to the first optical system and is configured to process the laser beam emitted from the laser generating device and to irradiate the processed laser beam onto the substrate. The path switching member is configured to switch a path of the laser beam emitted from the laser generating device and to alternately distribute the laser beam to the first and second optical systems.

### BACKGROUND

1. Field

Embodiments relate to a crystallization apparatus, a crystallization method, and a method of manufacturing an organic light-emitting display device. Embodiments relate to a crystallization apparatus capable of performing crystallization of amorphous silicon by selectively using sequential lateral solidification (SLS) on partial areas of a substrate, e.g., by including at least one laser generating device and a plurality of optical systems. Embodiments relate to a crystallization method and a method of manufacturing an organic light-emitting display device.

2. Description of the Related Art

An active matrix type (AM) organic light-emitting display device may include a pixel driving circuit for each pixel. The pixel driving circuit may include a thin film transistor (TFT) formed of silicon. Amorphous silicon or polycrystalline silicon may be used as the silicon forming the TFT.

Methods of manufacturing such polycrystalline silicon may vary. For example, methods of manufacturing polycrystalline silicon may include directly depositing polycrystalline silicon and a depositing amorphous silicon and crystallizing the amorphous silicon.

### SUMMARY

Embodiments are directed to a crystallization apparatus, a crystallization method, and a method of manufacturing an organic light-emitting display device.

Embodiments may be realized by providing a crystallization apparatus, which uses sequential lateral solidification (SLS) and crystallizes an amorphous silicon layer formed on a substrate, the crystallization apparatus including: a laser generating device for emitting a laser beam; a first optical system for processing the laser beam emitted from the laser generating device and irradiating the processed laser beam onto the substrate; a second optical system formed parallel to the first optical system, and for processing the laser beam emitted from the laser generating device and irradiating the processed laser beam onto the substrate; and a path switching member for switching a path of the laser beam emitted from the laser generating device and alternately distributing the laser beam to the first and second optical systems.

The laser beam emitted from the laser generating device may be periodically alternately transmitted to the first and second optical systems.

The laser beam emitted from the laser generating device may be irradiated onto the substrate while the substrate moves relative to the crystallization apparatus.

A plurality of panels may be disposed on the substrate in parallel, the first optical system may be disposed to correspond to a first panel to crystallize the amorphous silicon layer on the first panel, and the second optical system may be disposed to correspond to a second panel to crystallize the amorphous silicon layer on the second panel.

The laser beam emitted from the laser generating device may be irradiated onto the first panel through the first optical system when the first optical system passes over a region that requires crystallization of the amorphous silicon layer on the first panel, and the laser beam emitted from the laser generating device may be irradiated onto the second panel through the second optical system when the second optical system passes over a region that requires crystallization of the amorphous silicon layer on the second panel.

The laser beam emitted from the laser generating device may be a pulse laser beam.

A laser irradiation region of the substrate, onto which the pulse laser beam is irradiated once, and a laser irradiation region, onto which the pulse laser beam is irradiated next, may be formed to partially overlap each other.

The amorphous silicon layer of the overlapped region may be crystallized by being melted and solidified twice.

The path switching member may include a reflective portion and a transmissive portion, wherein the reflective portion and the transmissive portion may be alternately disposed on a path of the laser beam.

When the transmissive portion is disposed on the path of the laser beam, the laser beam may be transmitted to the first optical system through the transmissive portion.

When the reflective portion is disposed on the path of the laser beam, the laser beam may be reflected at the reflective portion and transmitted to the second optical system.

The path switching member may perform a reciprocating motion with respect to the path of the laser beam.

The path switching member may include a prism, wherein the laser beam emitted from the laser generating device may be alternately irradiated onto a first surface and a second surface of the prism.

The path switching member may include a prism, wherein the prism may perform a reciprocating motion with respect to the path of the laser beam.

The laser generating device may include a first laser generating device and a second laser generating device.

Laser beams generated by the first and second laser generating devices may be pulse laser beams and are alternately irradiated onto the substrate.

The laser beam generated by the second laser generating device may be generated between pulses of the pulse laser beam generated by the first laser generating device.

Embodiments may also be realized by providing a crystallization method, which uses sequential lateral solidification (SLS) and crystallizes an amorphous silicon layer formed on a substrate on which a plurality of panels are disposed in parallel, the crystallization method including: forming the amorphous silicon layer on the substrate; relatively moving the substrate with respect to a crystallization apparatus; performing crystallization by alternately irradiating a laser beam onto a first panel and a second panel from among the plurality of panels, which are disposed parallel to each other, while the substrate relatively moves with respect to the crystallization apparatus.

The performing of the crystallization selectively may crystallize only a part of the amorphous silicon layer.

A laser beam emitted from a laser generating device may be irradiated onto the first panel when the laser generating device passes over a region that requires crystallization of the amorphous silicon layer on the first panel, and the laser beam emitted from the laser generating device may be irradiated onto the second panel when the laser generating device passes over a region that requires crystallization of the amorphous silicon layer on the second panel.

The performing of the crystallization may include selectively crystallizing only a region on which an active layer is formed, from among the amorphous silicon layer.

The laser beam irradiated onto the substrate may be a pulse laser beam, and the performing of the crystallization may include melting and solidifying the amorphous silicon layer by periodically irradiating the pulse laser beam onto the substrate while the substrate relatively moves with respect to the crystallization apparatus.

A laser irradiation region of the substrate, onto which the pulse laser beam is irradiated once, and a laser irradiation region, on which the pulse laser is irradiated next, may be formed to partially overlap each other.

The amorphous silicon layer of the overlapped region may be crystallized by being melted and solidified twice.

According to another aspect of the present invention, there is provided a crystallization method including: disposing a crystallization apparatus to be spaced apart from a substrate, the crystallization apparatus including: a laser generating device for emitting a laser beam; a first optical system for processing the laser beam emitted from the laser generating device and irradiating the processed laser beam onto the substrate; a second optical system formed parallel to the first optical system, and for processing the laser beam emitted from the laser generating device and irradiating the processed laser beam onto the substrate; and a path switching member for switching a path of the laser beam emitted from the laser generating device and alternately distributing the laser beam to the first and second optical systems,; and irradiating a laser beam emitted from the laser generating device to the substrate alternately through the first optical system and the second optical system, while the substrate relatively moves with respect to the crystallization apparatus.

Embodiments may also be realized by providing a method of manufacturing an organic light-emitting display device by using the crystallization method, wherein the organic light-emitting display device includes a plurality of pixels each including a channel region, a storage region, and a light-emitting region, wherein the performing of the crystallization includes crystallizing only the channel region and the storage region.

### BRIEF DESCRIPTION OF THE DRAWINGS

Features and advantages of the present invention will become more apparent by describing in detail exemplary embodiments thereof with reference to the attached drawings in which:

FIG. 1 illustrates a diagram schematically showing a crystallization apparatus, according to an exemplary embodiment;

FIG. 2 illustrates a plan view schematically showing an organic light-emitting display device manufactured by using the crystallization apparatus of FIG. 1;

FIG. 3 illustrates a plan view of one pixel from among a plurality of pixels forming the organic light-emitting display device of FIG. 2, according to an exemplary embodiment;

FIG. 4 illustrates a cross-sectional view taken along a line A-A of FIG. 3;

FIG. 5 illustrates a diagram for describing an exemplary process of crystallizing a substrate by using a laser beam irradiated from a laser generating device;

FIG. 6 illustrates a diagram showing in detail an exemplary path switching member of the crystallization apparatus of FIG. 1;

FIG. 7 illustrates a plan view of a control member of FIG. 6;

FIGS. 8 through 11 illustrate diagrams of path switching members of the crystallization apparatus of FIG. 1, according to exemplary embodiments;

FIG. 12 illustrates a diagram schematically showing a crystallization apparatus, according to another exemplary embodiment;

FIG. 13 illustrates a graph showing a pulse laser waveform in the crystallization apparatus of FIG. 1;

FIG. 14 illustrates a graph showing a pulse laser waveform in the crystallization apparatus of FIG. 12; and

FIG. 15 illustrates a diagram schematically showing a crystallization apparatus, according to another exemplary embodiment.

### DETAILED DESCRIPTION

This application claims the benefit of Korean Patent Application No. 10-2010-0109777, filed on Nov. 5, 2010, in the Korean Intellectual Property Office, and entitled: “Crystallization Apparatus, Crystallization Method, and Method of Manufacturing Organic Light-Emitting Display Device, Which Use Sequential Lateral Solidification,” the disclosure of which is incorporated herein in its entirety by reference.

Hereinafter, exemplary embodiments will be described more fully with reference to the accompanying drawings. The invention may, however, be embodied in many different forms and should not be construed as being limited to the embodiments set forth herein; rather, these embodiments are provided so that this disclosure will be thorough and complete, and will fully convey the concept of the invention to those of ordinary skill in the art.

In the figures, the dimensions of layers and regions may be exaggerated for clarity of illustration. It will also be understood that when a layer or element is referred to as being “on” another layer, substrate, or element, it can be directly on the other layer, substrate, or element, or intervening layers may also be present.

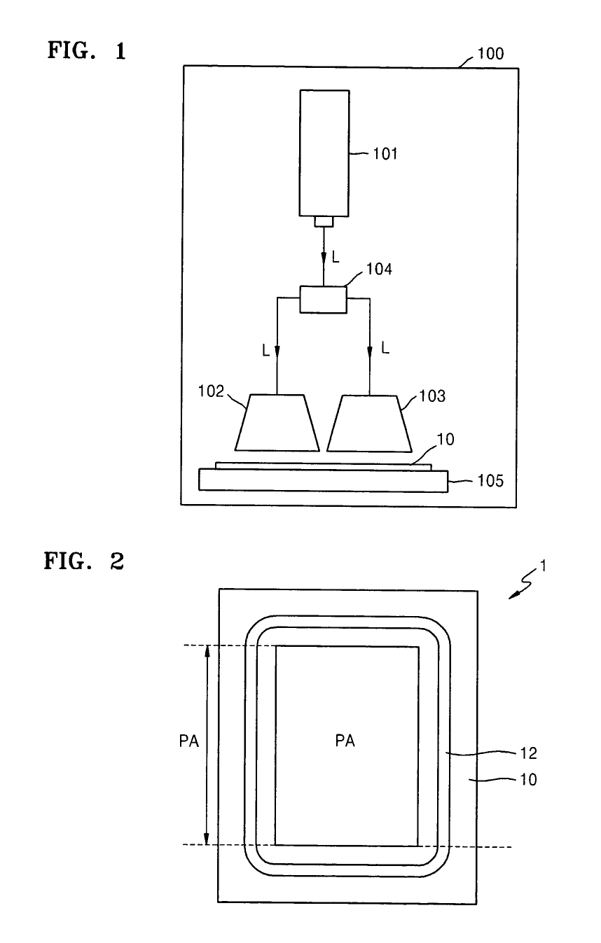

FIG. 1 is a diagram schematically illustrating a crystallization apparatus 100 according to an exemplary embodiment.

Referring to FIG. 1, the crystallization apparatus 100 according to the current embodiment may include a laser generating device 101 that is configured to generate a laser beam L. The crystallization apparatus 100 may include first optical system 102 that is configured to process the laser beam L emitted from the laser generating device 101 and to irradiate the processed laser beam L onto a first substrate 10. The crystallization apparatus 100 may include a second optical system 103 that is formed parallel to the first optical system, and that is configured to process the laser beam L emitted from the laser generating device 101 and to irradiate the processed laser beam L onto the first substrate 10. The crystallization apparatus 100 may include a path switching member 104 that is configured to switch a path of the laser beam L emitted from the laser generating device 101 to alternately distribute the laser beam L to either the first optical system 102 or the second optical system 103.

Here, each of the first and second optical systems 102 and 103 may include at least one of an attenuator (not shown) that adjusts the intensity of the laser beam L that is emitted from the laser generating device 101 and not processed, a focusing lens (not shown) that focuses the laser beam L emitted from the laser generating device 101, and a reducing lens (not shown) that reduces the laser beam L that penetrates through the focusing lens to a certain ratio.

An x-y stage 105, on which the first substrate 10 that is deposited with an amorphous silicon layer may be fixed, may be disposed at a location corresponding to the laser generating device 101. In order to crystallize the entire region of the first substrate 10, the x-y stage 105 may be relatively moved with respect to the first substrate 10, thereby expanding a crystallization region.

A structure of an organic light-emitting display device 1 manufactured by using the crystallization apparatus 100 will now be described in detail.

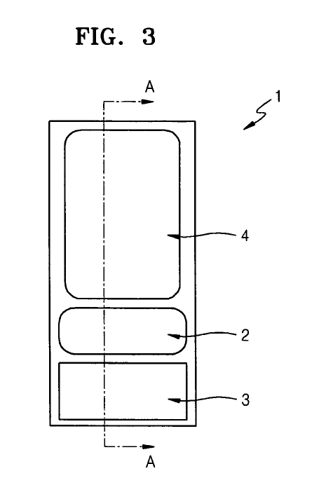

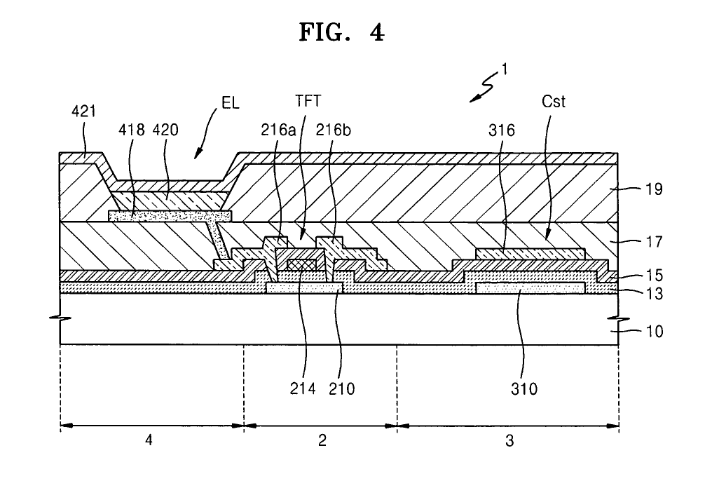

FIG. 2 is a plan view schematically illustrating the organic light-emitting display device 1 manufactured by using the crystallization apparatus 100 of FIG. 1, FIG. 3 is a plan view of one pixel from among a plurality of pixels forming the organic light-emitting display device 1 of FIG. 2, according to an exemplary embodiment, and FIG. 4 is a cross-sectional view taken along a line A-A of FIG. 3.

Referring to FIG. 2, the organic light-emitting display device 1 according to an exemplary embodiment may include the first substrate 10 having a thin film transistor (TFT), an organic light-emitting device EL, etc., and a second substrate (not shown) adhered to the first substrate 10, e.g., by a sealing member 12.

The first substrate 10 may include a plurality of pixels each including the TFT, the organic light-emitting device EL, and a storage capacitor Cst. The first substrate 10 may be, e.g., a low temperature polycrystalline silicon (LTPS) substrate, a glass substrate, a plastic substrate, or a stainless steel (SUS) substrate.

The second substrate may be an encapsulation substrate disposed on the first substrate 10, e.g., so as to block external moisture and air from penetrating into the TFT and the organic light-emitting device EL of the first substrate 10. The second substrate may be disposed to face the first substrate 10. The first substrate 10 and the second substrate may be combined to each other by the sealing member 12 disposed along edges of the first substrate 10 and the second substrate. The second substrate may be, e.g., a transparent substrate formed of glass or plastic.

The first substrate 10 may include a pixel region (PA pixel region), e.g., from which a light is emitted. The first substrate 10 may include a circuit region (not shown) disposed around the pixel region PA. According to exemplary embodiments, the sealing member 12 may be disposed on the circuit region around the pixel region PA, thereby adhering the first substrate 10 and the second substrate.

The organic light-emitting display device 1 according to an exemplary embodiment may performs selective crystallization on a semiconductor layer of the pixel region PA. Such selective crystallization will be described in detail later.

Referring to FIGS. 3 and 4, one pixel of the organic light-emitting display device 1 may include a channel region 2, a storage region 3, and a light-emitting region 4. The channel region 2, the storage region 3, and the light-emitting region 4 may be formed parallel to each other along one direction in FIG. 3, but locations of the channel region 2, the storage region 3, and the light-emitting region 4 are not limited thereto. For example, the storage region 3 and the light-emitting region 4 may be formed adjacent to each other along a lengthwise direction, and the channel region 2 may be formed at each side of and adjacent to each of the storage region 3 and the light-emitting region 4.

The channel region 2 may include the TFT as a driving device. The TFT may include an active layer 210, a gate electrode 214, and source and drain electrodes 216a and 216b. A first insulation layer 13 may be disposed between the gate electrode 214 and the active layer 210, e.g., to insulate the gate electrode 214 and the active layer 210 from each other. Also, source and drain regions, into which high density impurities may be injected, may be formed on each edge of the active layer 210, and may be respectively connected to the source and drain electrodes 216a and 216b.

The storage region 3 may include the storage capacitor Cst. The storage capacitor Cst may include a first capacitor electrode 310 and a second capacitor electrode 316, wherein the first insulation layer 13 may be disposed therebetween. The first capacitor electrode 310 may be formed on the same layer and of the same material as the TFT and the active layer 210. The second capacitor electrode 316 may be formed on the same layer and of the same material as the source and drain electrodes 216a and 216b of the TFT.

The light-emitting region 4 may include the organic light-emitting device EL.

The organic light-emitting device EL may include a pixel electrode 418 connected to one of the source and drain electrodes 216a and 216b of the TFT, a counter electrode 421 facing the pixel electrode 418, and an intermediate layer 420 disposed therebetween. The pixel electrode 418 may be formed of, e.g., a transparent conductive material.

In an exemplary method of crystallization using a sequential lateral solidification (SLS) method, the entire region of a pixel region, i.e., all of a channel region, a storage region, and a light-emitting region may be crystallized. However, as organic light-emitting display devices have increased in size, an area to be crystallized has also enlarged. Accordingly, maintenance costs for a laser generating device to generate a laser beam have increased, while productivity has deteriorated.

Regions that may require high electron mobility in one pixel may be the channel region 2 and the storage region 3. The light-emitting region 4, which occupies more than half of the entire area of the pixel, may not require high electron mobility. Accordingly, it may be more efficient, e.g., better, to crystallize only the channel region 2 and the storage region 3 in terms of, e.g., laser maintenance costs.

Accordingly, the organic light-emitting display device 1 may be characterized in that it forms an active layer in a polycrystalline silicon state by selectively crystallizing, e.g., only crystallizing, semiconductor layers formed in the channel region 2 and the storage region 3. A semiconductor layer in the light-emitting region 4 may not be crystallizing, may be substantially not crystallized, or may only be minimally crystallized. In other words, while one of a substrate and a laser generating device relatively moves with respect to the other, crystallization may be performed on portions where crystallization is desired, e.g., only on portions of the channel region 2 and storage region 3.

By performing the selective crystallization as such, efficiency of a laser generating device may be maximized, and maintenance costs may be reduced while productivity may be improved.

The selective crystallization may be performed by the crystallization apparatus 100 of FIG. 1. In other words, referring to FIG. 1, the laser beam generated by one laser generating device 101 may be alternately transmitted to the first optical system 102 and the second optical system 103 by the path switching member 104. While the first optical system 102 performs crystallization while passing over the channel region 2 and the storage region 3 of the first panel of the first substrate 10, the second optical system 103 may pass over the light-emitting region 4 of the second panel. Alternatively, while the second optical system 103 performs crystallization while passing over the channel region 2 and the storage region 3 of the second panel of the first substrate 10, the first optical system 102 may pass over the light-emitting region 4 of the first panel.

This will now be described in detail.

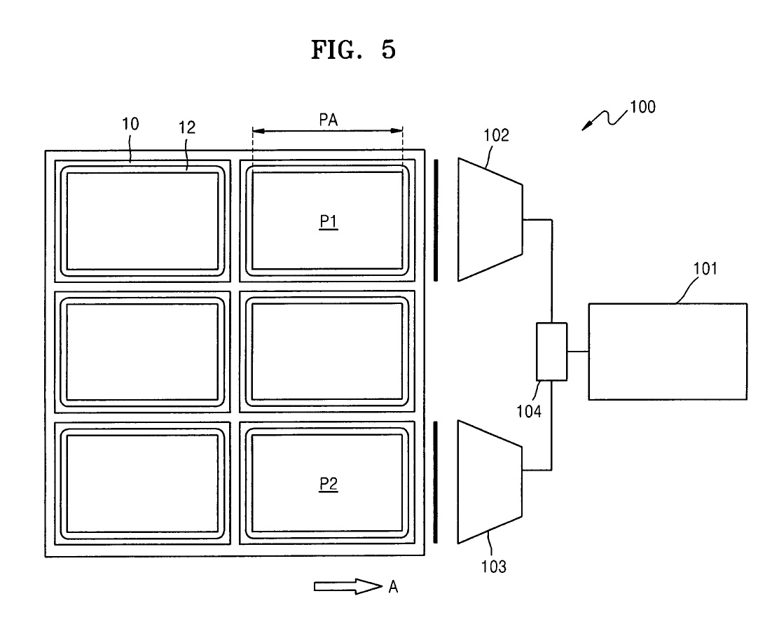

FIG. 5 is a diagram for describing a process of crystallizing the first substrate 10 by using a laser beam irradiated from the laser generating device 101. As shown in FIG. 5, when an organic light-emitting display device is enlarged, a plurality of panels, i.e., organic light-emitting display devices, may be formed on one mother glass. Here, as shown in FIG. 5, when the panels are arranged in a plurality of lines, the laser beam irradiated through the first optical system 102 may crystallize a first panel P1 disposed on a first line, and the laser beam irradiated through the second optical system 103 may crystallize a second panel P2 disposed in a third line.

In detail, when the laser beam emitted from the laser generating device 101 is transmitted to the first optical system 102 by the path switching member 104, while the first substrate 10 moves in a direction indicated by an arrow A with respect to the crystallization apparatus 100, the laser beam that passed through the first optical system 102 may be irradiated onto the first panel P1 to crystallize certain regions, e.g., a channel region and a storage region, of the first panel P1. Here, the second optical system 103 may pass over a region of the second panel P2 that does not require crystallization, e.g., a light-emitting region.

Here, when the first panel P1 is completed being crystallized, the path switching member 104 may switch a path of the laser beam so that the laser beam is irradiated to the second optical system 103. In other words, when the laser beam emitted from the laser generating device 101 is transmitted to the second optical system 103 by the path switching member 104, the laser beam that passed through the second optical system 103 may be irradiated onto the second panel P2 to crystallize regions of the second panel P2, e.g., a channel region and a storage region of the second panel P2. Here, the first optical system 102 may pass over a region of the first panel P1 that does not require crystallization, e.g., a light-emitting region of the first panel P1.

In other words, when the first optical system 102 passes over the channel region and the storage region of the first panel P1, the path switching member 104 may transmit the laser beam to the first optical system 102, thereby crystallizing the channel region and the storage region of the first panel P1. Also, when the second optical system 103 passes over the channel region and the storage region of the second panel P2, the path switching member 104 may transmit the laser beam to the second optical system 103, thereby crystallizing the channel region and the storage region of the second panel P2.

As such, the selective crystallization may be performed by repeatedly and alternately crystallizing the channel and storage regions of the first panel P1 and the channel and storage regions of the second panel P2 while relatively moving the first substrate 10 with respect to the crystallization apparatus 100.

Here, the selective crystallization may be performed by disposing the second optical system 103 away from the first optical system 102 by a predetermined distance, e.g., by an offset corresponding to a width of a non-crystallization region.

A method of crystallizing an amorphous silicon layer by applying an SLS method by using a crystallization apparatus, according to an exemplary embodiment will now be described in detail.

A crystalline silicon layer may be formed by forming a buffer layer (not shown) constituting an insulation layer on the first substrate 10, depositing an amorphous silicon layer on the buffer layer, and then crystallizing the amorphous silicon layer. Embodiments may include omitting the buffer layer.

The laser beam generated by the laser generating device 101 of the crystallization apparatus 100 may be a pulse laser beam, e.g., the laser beam may not be a continuous wave (CW) laser beam. For example, when the laser generating device 101 generates a pulse laser beam having a frequency of about 6,000 Hz, a high frequency laser beam may be irradiated about 6,000 times onto the first substrate 10 for about 1 second.

When the pulse laser beam generated by the laser generating device 101 is irradiated onto the first substrate 10, grains may be laterally grown from two interfaces of the amorphous silicon layer in a melting region where the pulse laser beam is irradiated. The grains may stop growing as grain boundaries collide with each other, and a core generating region may not substantially exist, e.g., may not exist, between the grains. When a moving speed of the laser generating device 101 is adjusted, e.g., so that a following laser irradiation region somewhat overlaps with a current laser irradiation region, a two-shot crystallization effect may be obtained via a single scan in one direction.

In other words, when the pulse laser beam generated by the laser generating device 101 is irradiated onto the first substrate 10 for a first time, poly silicon may be formed as the amorphous silicon layer is melted and solidified in the melting region on which the pulse laser beam is irradiated. Then, the laser generating device 101 may move a certain distance in one direction during a resting period between pulses of the pulse laser beam. Here, the moving speed of the laser generating device 101 may be adjusted so that the following laser irradiation region, i.e., the melting region, somewhat overlaps with the current laser irradiation region. At this time, when the pulse laser beam is irradiated onto the first substrate 10 for a second time, the poly silicon is melted and solidified again to be crystallized in a portion where the laser irradiation region where the pulse laser beam is irradiated for the first time and the laser irradiation region where the pulse laser beam is irradiated for the second time overlap each other. As such, a channel region and a storage region of one pixel may be crystallized by periodically irradiating the laser beam while moving the laser generating device 101 in one direction.

The path switching member 104 of the crystallization apparatus 100, according to various exemplary embodiments will now be described.

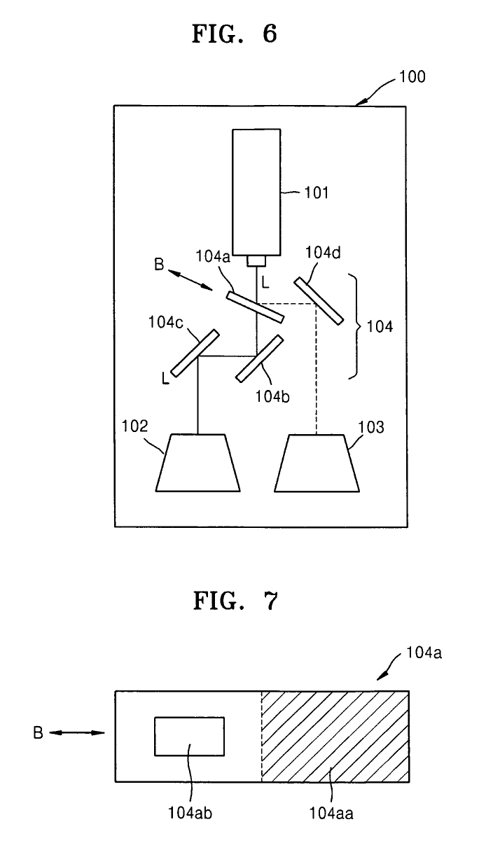

FIG. 6 is a diagram illustrating in detail the path switching member 104 of the crystallization apparatus 100 of FIG. 1, and FIG. 7 is a plan view of a control member 104a of FIG. 6.

Referring to FIGS. 6 and 7, the path switching member 104 of the crystallization apparatus 100 may include the control member 104a, a first reflective mirror 104b, a second reflective mirror 104c, and a third reflective mirror 104d. Also, the control member 104a may include a reflective portion 104aa and a transmissive portion 104ab. The control member 104a may be disposed in such a way that reciprocating motion is possible in a direction indicated by an arrow B. In other words, the reflective portion 104aa and the transmissive portion 104ab may be alternately disposed on the path of the laser beam L emitted from the laser generating device 101, thereby alternately distributing the laser beam to the first optical system 102 and the second optical system 103. This will now be described in detail.

When the channel region and the storage region of the first panel P1 of FIG. 5 disposed below the first optical system 102 may be crystallized by using the laser beam L emitted from the laser generating device 101, the transmissive portion 104ab of the control member 104a may be disposed on the path of the laser beam L emitted from the laser generating device 101. Accordingly, the laser beam L emitted from the laser generating device 101 may pass through the transmissive portion 104ab of the control member 104a, and may be irradiated onto the first panel P1 through the first reflective mirror 104b and the second reflective mirror 104c.

On the other hand, when the channel region and the storage region of the second panel P2 of FIG. 5 disposed below the second optical system 103 are to be crystallized by using the laser beam L emitted from the laser generating device 101, the reflective portion 104aa of the control member 104a may be disposed on the path of the laser beam L emitted from the laser generating device 101. Accordingly, the path of the laser beam L emitted from the laser generating device 101 may be switched by being reflected at the reflective portion 104aa of the control member 104a, and the laser beam L may be irradiated onto the second panel P2 through the third reflective mirror 104d.

As such, the path of the laser beam L emitted from the laser generating device 101 may be controlled as the control member 104a reciprocatedly moves, e.g., in the direction indicated by the arrow B, and thus the crystallization may be selectively performed only on required portions on the first and second panels P1 and P2.

Here, the control member 104a may be formed to have a certain angle. The certain angle of the control member 104a may be changeable to realize maximum energy transmission.

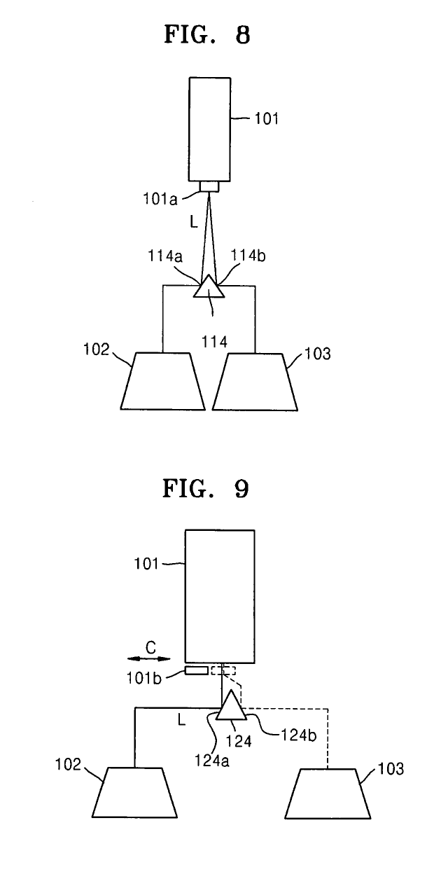

FIGS. 8 through 11 are diagrams of path switching members of the crystallization apparatus 100 of FIG. 1, according to exemplary embodiments.

According to an exemplary embodiment. as shown in FIG. 8, a path switching member 114 may be a prism. Here, at least two flat surfaces of the path switching member 114 may reflect light. A mirror 101a for controlling an angle of the laser beam L emitted from the laser generating device 101 may be disposed on one side of the laser generating device 101. The mirror 101a may rotate by using an irradiation direction of the laser beam L as an axis so as to, e.g., control the path of the laser beam L emitted from the laser generating device 101 in such a way that the laser beam L is alternately transmitted to different surfaces of the path switching member 114. When the laser beam L is irradiated on a first surface 114a of the path switching member 114, the laser beam L may be reflected at the first surface 114a and may be then incident on the first optical system 102. Alternately, when the laser beam L is irradiated on a second surface 114b of the path switching member 114, the laser beam L may be reflected at the second surface 114b and may be then incident on the second optical system 103.

According to another exemplary embodiment, a path switching member 124 may be a prism as shown in FIG. 9. A mirror 101b that controls an angle of the laser beam L emitted from the laser generating device 101 may be disposed on one side of the laser generating device 101. The mirror 101a may reciprocatedly move in a direction indicated by an arrow C so as to, e.g., control the path of the laser beam L emitted from the laser generating device 101 in such a way that the laser beam L is alternately transmitted to different surfaces of the path switching member 124. Accordingly, when the laser beam L is irradiated on a first surface 124a of the path switching member 124, the laser beam L may be reflected at the first surface 124a and may be incident on the first optical system 102. Alternatively, when the laser beam L is irradiated on a second surface 124b of the path switching member 124, the laser beam L may be reflected at the second surface 124b and may be incident on the second optical system 103.

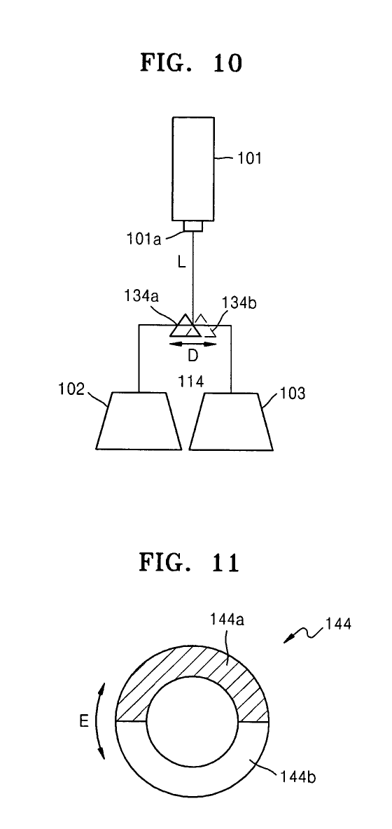

According to another exemplary embodiment, a path switching member 134 may be a prism as shown in FIG. 10. The path switching member 134 may be configured to reciprocatedly move by itself in a direction indicated by an arrow D. Accordingly, when the path switching member 134 is disposed on a first location indicated in a solid line, the laser beam L may be reflected at a first surface 134a and may be incident on the first optical system 102. When the path switching member 134 is disposed on a second location indicated in a dotted line, the laser beam L may be reflected at a second surface 134b and may be incident on the second optical system 103.

According to another exemplary embodiment, a path switching member 144 may be a rotating member including a reflective portion 144a and a transmissive portion 144b, as shown in FIG. 11. The reflective portion 144a and the transmissive portion 144b may be alternately disposed on the path of the laser beam L emitted from the laser generating device 101 as the path switching member 144 rotates in a direction indicated by an arrow E, and thus the laser beam L may be alternately distributed to the first optical system 102 and the second optical system 103.

According to another exemplary embodiment, as shown in FIG. 11, a path switching member 144 may be a rotating member including a first transmissive portion 144a and a second transmissive portion 144b. Here, both the first and second transmissive portions 144a and 144b may penetrate the laser beam L, but one of them may refract the laser beam L. The first transmissive portion 144a and the second transmissive portion 144b may be alternately disposed on the path of the laser beam L emitted from the laser generating device 101 as the path switching member 144 rotates in the direction indicated by the arrow E, and thus the laser beam L may be alternately distributed to the first and second optical systems 102 and 103.

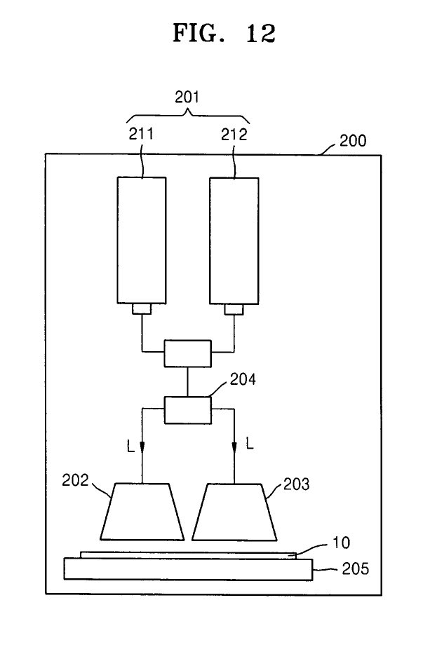

FIG. 12 is a diagram schematically illustrating a crystallization apparatus 200 according to another exemplary embodiment.

Referring to FIG. 12, the crystallization apparatus 200 according to the current exemplary embodiment may include a laser generating device 201 generating the laser beam L. The crystallization apparatus 200 may include a first optical system 202 processing the laser beam L emitted from the laser generating device 201 and irradiating the processed laser beam L onto the first substrate 10. The crystallization apparatus 200 may include a second optical system 203 formed in parallel to the first optical system 202, processing the laser beam L emitted from the laser generating device 201, and irradiating the processed laser beam L onto the first substrate 10. The crystallization apparatus 200 may include a path switching member 204 switching the path of the laser beam emitted from the laser generating device 201 to alternately distribute the laser beam L to the first and second optical systems 202 and 203. Here, the structures of the first and second optical systems 202 and 203, and the path switching member 204 may be similar to, e.g., identical to, those described above, and thus detailed descriptions thereof will not be repeated.

The laser generating device 201 of the crystallization apparatus 200 may include a first laser generating device 211 and a second laser generating device 212. The crystallization apparatus 200 according to the current embodiment may includes two, or at least two, laser generating devices and two, or at least two, optical systems. Each of structures of the first and second laser generating device 211 and 212 may be similar to, e.g., identical to, that of the laser generating device 101 of FIG. 1.

By including the two laser generating devices, i.e., the first and second laser generating devices 211 and 212, a production speed of the crystallization apparatus 200 may be improved by at least twice as much as that of the crystallization apparatus 100. Such an improved production speed will now be described in detail.

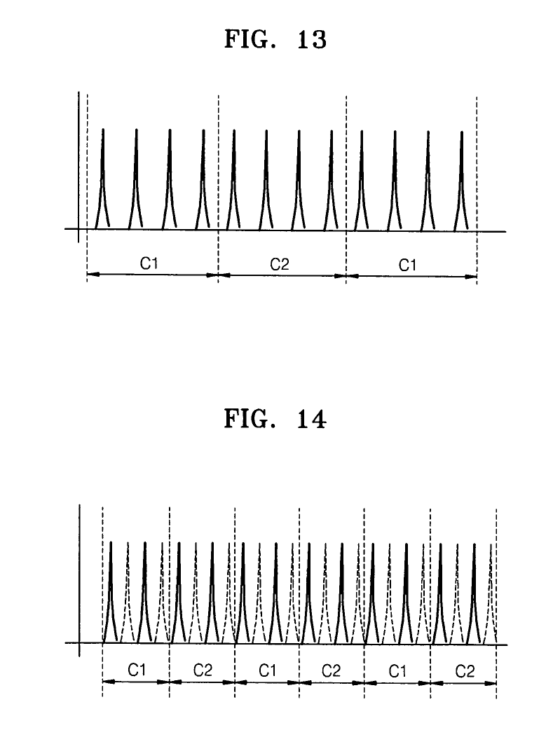

FIG. 13 is a graph showing a pulse laser waveform in the crystallization apparatus 100 of FIG. 1. For purposes of explanation of the FIG. 13, a laser beam is irradiated four times so as to crystallize all of crystallization regions, i.e., a channel region and a storage region, of one pixel. The frequency of a pulse laser generated by a laser generating device is about 6,000 Hz. Thus, it may take about 1/1500 seconds (about 1/6000 seconds×4 times) for the crystallization apparatus 100 to crystallize the crystallization region of one pixel. The path switching member 104 switches the path of the laser beam L once per about 1/1500 seconds to alternately crystallize the first and second panels P1 and P2 of FIG. 5.

FIG. 14 is a graph showing a pulse laser waveform in the crystallization apparatus 200 of FIG. 12. In the crystallization apparatus 200, there is a pulse delay of about a half wavelength between a laser beam generated by the first laser generating device 211 and a laser beam generated by the second laser generating device 212. In other words, the laser beam generated by the second laser generating device 212 is generated between pulses of a pulse laser generated by the first laser generating device 211. In detail, the laser beams generated by the first and second laser generating devices 211 and 212 are alternately irradiated on the first substrate 10. Accordingly, a time for a laser beam to be irradiated onto a substrate in the crystallization apparatus 200 is half that in the crystallization apparatus 100. Referring to FIGS. 13 and 14, three pixels are crystallized by the crystallization apparatus 100, while six pixels are crystallized by the crystallization apparatus 200 in the same amount of time.

Accordingly, a crystallization speed is improved.

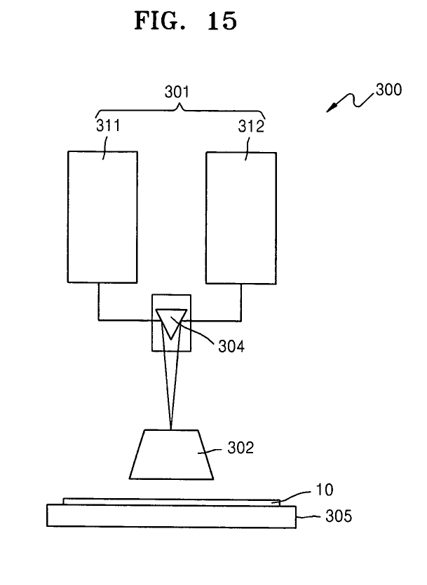

FIG. 15 is a diagram schematically illustrating a crystallization apparatus 300 according to another exemplary embodiment.

Referring to FIG. 15, the crystallization apparatus 300 according to the current exemplary embodiment may include a laser generating device 301 having a first laser generating device 311 and a second laser generating device 312 for generating the laser beam L. The crystallization apparatus 300 may include an optical system 302 for processing the laser beam L emitted from the laser generating device 301 and irradiating the processed laser beam L onto the first substrate 10. The crystallization apparatus 300 may include a path switching member 304 for concentrating the laser beam L emitted from the laser generating device 301 and switching the path of the laser beam L. Structures of the laser generating device 301 and the path switching member 304 may be similar to, e.g., identical to, those described in the previous embodiments, and thus detailed descriptions thereof will not be repeated.

In comparison to the crystallization apparatuses 100 and 200, the crystallization apparatus 300 may include only one optical system 302. For example, the crystallization apparatus 300 includes two laser generating devices, i.e., the first and second laser generating devices 311 and 312, while including only one optical system 302, and thus may have a production speed that is at least twice as high as that of the crystallization apparatuses 100 and 200 in crystallizing one panel.

If a frequency of a pulse laser generated by one laser generating device is about 6000 Hz, the pulse laser may be irradiated on one panel about 12,000 times per second, and thus a time taken to crystallize one panel is reduced by about half. Accordingly, a crystallization speed is further improved.

By view of summation and review, an amorphous silicon TFT (a-Si TFT) used in the pixel driving circuit may have a low electron mobility equal to or below about 1 cm²/Vs since a semiconductor active layer forming a source, a drain, and a channel is formed of amorphous silicon. Thus, recently, the a-Si TFT tends to be replaced by a polycrystalline silicon TFT (poly-Si TFT). The poly-Si TFT has relatively large electron mobility and excellent stability with respect to irradiation of light compared to the a-Si TFT. Accordingly, the poly-Si TFT is very suitable to drive an AM organic light-emitting display device and/or to be used as an active layer of a switching TFT.

Methods of manufacturing such polycrystalline silicon may vary, and may be classified into a method of directly depositing polycrystalline silicon and a method of depositing amorphous silicon and crystallizing the amorphous silicon.

Examples of the method of directly depositing polycrystalline silicon include, e.g., a chemical vapor deposition (CVD) method, a photo CVD method, a hydrogen radical (HR) CVD method, an electron cyclotron resonance (ECR) CVD method, a plasma enhanced (PE) CVD method, and a low pressure (LP) CVD method.

Meanwhile, examples of the method of depositing amorphous silicon and crystallizing the amorphous silicon include, e.g., a solid phase crystallization (SPC) method, an excimer laser crystallization (ELC) method, a metal induced crystallization (MIC) method, a metal induced lateral crystallization (MILC) method, and a sequential lateral solidification (SLS) method.

The SPC method may not be very practical because the SPC method may be performed for a long period of time at a high temperature equal to or above 600° C. The ELC method is capable of performing low temperature crystallization but uniformity may be low because a laser beam may be widened by using an optical system. The MIC method may have a low crystallization temperature because a metal thin film may be deposited on a surface of amorphous silicon, and a silicon layer may be crystallized by using the metal thin film as a crystallization catalyst. However, in the MIC method, characteristics of a TFT device formed of a polycrystalline silicon layer may be deteriorated because the polycrystalline silicon layer may be contaminated by a metal, and formed crystals may have a small size and the crystals may be distributed in a disorderly manner.

The SLS method uses characteristics that include, e.g., grains of silicon growing in a direction perpendicular to a boundary surface between liquid and solid. For example, crystallization may be performed by melting a part of amorphous silicon by penetrating a laser beam through a certain region by using a mask, and growing crystals toward a melted part of the amorphous silicon from a boundary between the melted part and an un-melted part of the amorphous silicon. The SLS method has received attention as a method of manufacturing low temperature poly-Si, as discussed above.

According to embodiments, when an amorphous silicon layer is crystallized by using an SLS method, e.g., laser use may be efficiency increased and maintenance costs may be reduced. Embodiments include a crystallization apparatus, a crystallization method, and a method of manufacturing an organic light-emitting display device.

More specifically, embodiments are directed to a crystallization apparatus, wherein laser use efficiency may be increased and maintenance costs may be reduced by crystallizing amorphous silicon by, e.g., selectively using sequential lateral solidification (SLS) on a partial area of a substrate, a crystallization method, and a method of manufacturing an organic light-emitting display device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A crystallization apparatus, which uses sequential lateral solidification (SLS) and crystallizes an amorphous silicon layer formed on a substrate, the crystallization apparatus comprising:
a laser generating device configured to emit a laser beam;
a first optical system configured to process the laser beam emitted from the laser generating device and to irradiate the processed laser beam onto the substrate;
a second optical system parallel to the first optical system, the second optical system being configured to process the laser beam emitted from the laser generating device and to irradiate the processed laser beam onto the substrate; and
a path switching member configured to switch a path of the laser beam emitted from the laser generating device and to alternately distribute the laser beam to the first and second optical systems.

2. The crystallization apparatus of claim 1, wherein the laser beam emitted from the laser generating device is periodically alternately transmitted to the first and second optical systems.

3. The crystallization apparatus of claim 1, wherein the laser beam emitted from the laser generating device is irradiated onto the substrate while the substrate moves relative to the crystallization apparatus.

4. The crystallization apparatus of claim 3, wherein the first optical system corresponds to a first panel of a plurality of panels on the substrate and is configured to crystallize the amorphous silicon layer on the first panel, and the second optical system corresponds to a second panel of the plurality of panels on the substrate and is configured to crystallize the amorphous silicon layer on the second panel.

5. The crystallization apparatus of claim 4, wherein the laser beam emitted from the laser generating device is configured to be irradiated onto the first panel through the first optical system when the first optical system passes over a region that requires crystallization of the amorphous silicon layer on the first panel, and the laser beam emitted from the laser generating device is configured to be irradiated onto the second panel through the second optical system when the second optical system passes over a region that requires crystallization of the amorphous silicon layer on the second panel.

6. The crystallization apparatus of claim 1, wherein the laser beam emitted from the laser generating device is a pulse laser beam.

7. The crystallization apparatus of claim 6, wherein a laser irradiation region of the substrate, onto which the pulse laser beam is irradiated once, and a laser irradiation region, onto which the pulse laser beam is irradiated next, are formed to partially overlap each other.

8. The crystallization apparatus of claim 7, wherein the amorphous silicon layer of the overlapping first and second irradiation regions are configured to be crystallized by being melted and by being solidified twice.

9. The crystallization apparatus of claim 1, wherein the path switching member includes a reflective portion and a transmissive portion, the reflective portion and the transmissive portion being alternately arranged on a path of the laser beam.

10. The crystallization apparatus of claim 9, wherein the laser beam is transmitted to the first optical system through the transmissive portion.

11. The crystallization apparatus of claim 9, wherein the laser beam is reflected at the reflective portion and transmitted to the second optical system.

12. The crystallization apparatus of claim 9, wherein the path switching member is configured to perform a reciprocating motion with respect to the path of the laser beam.

13. The crystallization apparatus of claim 1, wherein the path switching member includes a prism, and the laser beam emitted from the laser generating device is alternately irradiated onto a first surface and a second surface of the prism.

14. The crystallization apparatus of claim 1, wherein the path switching member includes a prism, the prism being configured to perform a reciprocating motion with respect to the path of the laser beam.

15. The crystallization apparatus of claim 1, wherein the laser generating device includes a first laser generating device and a second laser generating device.

16. The crystallization apparatus of claim 15, wherein laser beams generated by the first and second laser generating devices are pulse laser beams that are alternately irradiated onto the substrate.

17. The crystallization apparatus of claim 16, wherein the laser beam generated by the second laser generating device is generated between pulses of the pulse laser beam generated by the first laser generating device.

18. A crystallization method, which uses sequential lateral solidification (SLS) and crystallizes an amorphous silicon layer formed on a substrate on which a plurality of panels are disposed in parallel, the crystallization method comprising:
forming the amorphous silicon layer on the substrate;
moving the substrate with respect to a crystallization apparatus;
performing crystallization while the substrate moves with respect to the crystallization apparatus, the performing of the crystallization being carried out by alternately irradiating a laser beam onto a first panel and a second panel from among the plurality of panels, the first panel and the second panel being disposed parallel to each other.

19. The crystallization method of claim 18, wherein the performing of the crystallization selectively crystallizes only a part of the amorphous silicon layer.

20. The crystallization method of claim 19, wherein a laser beam emitted from a laser generating device is irradiated onto the first panel when the laser generating device passes over a region that requires crystallization of the amorphous silicon layer on the first panel, and the laser beam emitted from the laser generating device is irradiated onto the second panel when the laser generating device passes over a region that requires crystallization of the amorphous silicon layer on the second panel.

21. The crystallization method of claim 19, wherein the performing of the crystallization includes selectively crystallizing only a region of the amorphous silicon layer on which an active layer is formed.

22. The crystallization method of claim 18, wherein the laser beam irradiated onto the substrate is a pulse laser beam, and the performing of the crystallization includes melting and solidifying the amorphous silicon layer by periodically irradiating the pulse laser beam onto the substrate while the substrate moves with respect to the crystallization apparatus.

23. The crystallization method of claim 22, wherein the pulse laser beam is irradiated once onto a first laser irradiation region of the substrate, and the pulse laser is next irradiated onto a second laser irradiation region of the substrate, the first and second laser irradiation regions partially overlapping each other.

24. The crystallization method of claim 23, wherein the amorphous silicon layer of the overlapped region is crystallized by being melted and solidified twice.

25. A crystallization method, which uses a crystallization apparatus including a laser generating device, a first optical system, a second optical system formed parallel to the first optical system, and a path switching member, the crystallization apparatus being spaced apart from a substrate, the method comprising:
emitting a laser beam from the laser generating device;
processing the laser beam emitted from the laser generating device and irradiating the processed laser beam onto the substrate in the first optical system;
processing the laser beam emitted from the laser generating device and irradiating the processed laser beam onto the substrate in second optical system;
switching a path of the laser beam emitted from the laser generating device and irradiating the laser beam emitted from the laser generating device to the substrate alternately through the first optical system and the second optical system using the path switching member, while moving the substrate with respect to the crystallization apparatus.

26. A method of manufacturing an organic light-emitting display device by using the crystallization method of claim 18, the organic light-emitting display device including a plurality of pixels each including a channel region, a storage region, and a light-emitting region, wherein the performing of the crystallization includes crystallizing only the channel region and the storage region.
